(19) United States
(12) Patent Application Publication
(10) Pub. No.: US 2026/0165054 A1
(43) Pub. Date: Jun. 11, 2026

(54) METHOD OF MANUFACTURING INTEGRATED CIRCUIT DEVICE

(71) Applicant: SAMSUNG ELECTRONICS CO., LTD., Suwon-si (KR)

(72) Inventors: Youngseo KIM, Suwon-si (KR); Shingo NAKAMURA, Osaka (JP); Haruna MORI, Osaka (JP); Buseo CHOI, Suwon-si (KR); Takehiko KEZUKA, Osaka (JP); Wonwoong CHUNG, Suwon-si (KR); Youn Joung CHO, Suwon-si (KR)

(73) Assignees: SAMSUNG ELECTRONICS CO., LTD., Suwon-si (KR); DAIKIN INDUSTRIES, LTD., Osaka (JP)

(21) Appl. No.: 19/273,643

(22) Filed: Jul. 18, 2025

(30) Foreign Application Priority Data
Dec. 9, 2024 (KR) 10-2024-0181951

(51) Int. Cl. H01L 21/311; C09K 13/00; H10D 30/01

(52) U.S. Cl. CPC H10P 50/283; C09K 13/00; H10D 30/019

(57) ABSTRACT

A method of manufacturing an integrated circuit device includes selectively etching only a silicon oxide film from among the silicon oxide film and a nitride film on a substrate in a plasma atmosphere by using an etching gas including at least one compound from among hydrofluorocarbons and perfluorocarbons. The etching includes repeating, at least once, one cycle including first to third sub-operations having respective, different combinations of supply gases applied onto the substrate. The first sub-operation using a first plasma atmosphere obtained from the etching gas and an inert gas, the second sub-operation using a second plasma atmosphere obtained from the inert gas while the etching gas is blocked from being supplied to the substrate, and the third sub-operation using a third plasma atmosphere obtained from at least two gases including the inert gas and an oxygen-containing reactive gas.

### CROSS-REFERENCE TO RELATED APPLICATION

This application is based on and claims priority under 35 U.S.C. § 119 to Korean Patent Application No. 10-2024-0181951, filed on Dec. 9, 2024, in the Korean Intellectual Property Office, the disclosure of which is incorporated by reference herein in its entirety.

### BACKGROUND

### 1. Field

Some embodiments of the present disclosure relate to a method of manufacturing an integrated circuit device, and more particularly, a method of manufacturing an integrated circuit device, the method including a process of etching a silicon oxide film.

### 2. Description of Background Art

Due to the advance of electronics technology, integrated circuit devices have been rapidly down-scaled, and thus, patterns constituting electronic devices have been reduced to finer sizes. Therefore, there is a need for a technique capable of strictly controlling critical dimensions (CDs) of patterns intended to be formed, by sufficiently securing etch selectivity to selectively etch only a certain film including a particular material from a surface at which a plurality of films including different materials are exposed, in a manufacturing process of an integrated circuit device.

### SUMMARY

According to some embodiments of the present disclosure, a method of manufacturing an integrated circuit device may be provided, the method improving manufacturing process efficiency and reliability of the integrated circuit device as well as the dimensional precision of patterns by preventing unintended consumption of a nitride film and by strictly controlling critical dimensions (CDs) of patterns intended to be formed, when a silicon oxide film is selectively etched from a surface at which the silicon oxide film and the nitride film are exposed in a manufacturing process of the integrated circuit device.

According to some embodiments of the present disclosure, a method of manufacturing an integrated circuit device may be provided and include: forming, on a substrate, a structure including a silicon oxide film and a nitride film; and performing selective cycle etching that selectively etches only the silicon oxide film from among the silicon oxide film and the nitride film in a plasma atmosphere by using an etching gas including at least one compound selected from among a hydrofluorocarbon and a perfluorocarbon, wherein the performing the selective cycle etching includes repeating, at least once, one cycle including a first sub-operation, a second sub-operation after the first sub-operation, and a third sub-operation after the second sub-operation, wherein the first sub-operation, the second sub-operation, and the third sub-operation include applying respective, different combinations of supply gases onto the substrate in a reaction chamber, wherein the first sub-operation includes using a first plasma atmosphere obtained from the etching gas and an inert gas, wherein the second sub-operation includes using a second plasma atmosphere obtained from the inert gas while the etching gas is blocked from being supplied to the reaction chamber, and wherein the third sub-operation includes using a third plasma atmosphere obtained from at least two gases including the inert gas and an oxygen-containing reactive gas.

According to some embodiments of the present disclosure, a method of manufacturing an integrated circuit device may be provided and include: forming, on a substrate, a transistor and a structure that is on the transistor, the structure including a silicon oxide film and a nitride film; and forming, while the silicon oxide film and the nitride film on the substrate are exposed, a hole that exposes a portion of the transistor through the silicon oxide film, the forming including performing selective cycle etching that selectively etches only the silicon oxide film from among the silicon oxide film and the nitride film in a plasma atmosphere by using an etching gas including a hydrofluorocarbon, wherein the performing the selective cycle etching includes repeating, at least once, one cycle including a first sub-operation, a second sub-operation after the first sub-operation, and a third sub-operation after the second sub-operation, wherein the first sub-operation, the second sub-operation, and the third sub-operation include applying respective, different combinations of supply gases onto the substrate in a reaction chamber, wherein the first sub-operation includes forming a protection film on a surface of each of the silicon oxide film and the nitride film by using a first plasma atmosphere obtained from the etching gas and an inert gas, wherein the protection film includes radicals obtained from the hydrofluorocarbon, wherein the second sub-operation includes forming a volatile gas layer by a second plasma atmosphere obtained from the inert gas while the etching gas is blocked from being supplied to the reaction chamber, the volatile gas layer including volatile by-products obtained from an interface between the silicon oxide film and the protection film due to a reaction between the silicon oxide film and the protection film, and wherein the third sub-operation including separating the volatile by-products and the protection film from the surface of the silicon oxide film by a third plasma atmosphere obtained from at least two gases including the inert gas and an oxygen-containing reactive gas.

According to some embodiments of the present disclosure, a method of manufacturing an integrated circuit device may be provided and include: forming, on a substrate, a structure including a silicon oxide film and a nitride film; and performing selective cycle etching that selectively etches only the silicon oxide film from among the silicon oxide film and the nitride film in a plasma atmosphere by using an etching gas including an unsaturated compound having a boiling point of 0° C. or less at atmospheric pressure and represented by CₓH_{y}F_{z}, where 2≤x≤5, 1≤y≤9, and 1≤z≤9, wherein the selective cycle etching includes: a first sub-operation including forming a protection film on a surface of each of the silicon oxide film and the nitride film by exposing each of the silicon oxide film and the nitride film to a first plasma atmosphere obtained from the etching gas and an inert gas, wherein the protection film includes radicals obtained from the etching gas; a second sub-operation including forming a volatile gas layer by exposing a first resulting product having undergone the first sub-operation to a second plasma atmosphere obtained from the inert gas while the etching gas is blocked from being supplied to the first resulting product, wherein the volatile gas layer includes volatile by-products obtained from an interface between the silicon oxide film and the protection film due to a reaction between the silicon oxide film and the protection film; a third sub-operation including separating the volatile by-products and the protection film from the surface of the silicon oxide film by exposing a second resulting product having undergone the second sub-operation to a third plasma atmosphere obtained from at least two gases including the inert gas and an oxygen-containing reactive gas; and etching the silicon oxide film to an etch depth by repeating, a plurality of times, one cycle that includes the first sub-operation, the second sub-operation after the first sub-operation, and the third sub-operation after the second sub-operation.

According to some embodiments of the present disclosure, a system for manufacturing an integrated circuit device may be provided and include: a plasma etching apparatus; and a controller configured to control the plasma etching apparatus to: form, on a substrate, a structure including a silicon oxide film and a nitride film; and perform selective cycle etching that selectively etches only the silicon oxide film from among the silicon oxide film and the nitride film in a plasma atmosphere by using an etching gas including at least one compound selected from among a hydrofluorocarbon and a perfluorocarbon, wherein the controller is configured to control the plasma etching apparatus to perform the selective cycle etching by the plasma etching apparatus repeating, at least once, one cycle including a first sub-operation, a second sub-operation after the first sub-operation, and a third sub-operation after the second sub-operation, wherein the first sub-operation, the second sub-operation, and the third sub-operation include applying respective, different combinations of supply gases onto the substrate in a reaction chamber, wherein the first sub-operation includes using a first plasma atmosphere obtained from the etching gas and an inert gas, wherein the second sub-operation includes using a second plasma atmosphere obtained from the inert gas while the etching gas is blocked from being supplied to the reaction chamber, and wherein the third sub-operation includes using a third plasma atmosphere obtained from at least two gases including the inert gas and an oxygen-containing reactive gas.

According to some embodiments of the present disclosure, the etching gas includes the hydrofluorocarbon, and the hydrofluorocarbon includes a boiling point of 0° C. or less at atmospheric pressure.

According to some embodiments of the present disclosure, the controller is further configured to control the plasma etching apparatus to, after the selective cycle etching is finished, remove, by a purge process, reaction by-products from the reaction chamber, and is further configured to control the plasma etching apparatus to perform the selective cycle etching by the plasma etching apparatus sequentially repeating the first sub-operation, the second sub-operation, and the third sub-operation in the stated order a plurality of times without a process of removing the reaction by-products from the reaction chamber, until the selective cycle etching is finished.

### BRIEF DESCRIPTION OF DRAWINGS

Embodiments will be more clearly understood from the following detailed description taken in conjunction with the accompanying drawings in which:

FIGS. 1 and 2 are flowcharts illustrating a method of manufacturing an integrated circuit device, according to embodiments;

FIGS. 3A to 3E are cross-sectional views respectively illustrating a sequence of processes of a method of manufacturing an integrated circuit device, according to embodiments;

FIG. 4 is a diagram illustrating a schematic configuration of a plasma etching apparatus that may be used in a method of manufacturing an integrated circuit device, according to embodiments;

FIG. 5 is a timing pulse diagram illustrating a supply of a process gas in each of a plurality of sub-operations according to a method of manufacturing an integrated circuit device, according to embodiments;

FIG. 6 is a timing diagram illustrating the application or non-application of each of source power and bias power in each of a plurality of sub-operations according to a method of manufacturing an integrated circuit device, according to embodiments; and

FIGS. 7A to 7D are cross-sectional views respectively illustrating a sequence of processes of a method of manufacturing an integrated circuit device, according to some embodiments.

### DETAILED DESCRIPTION

Hereinafter, non-limiting example embodiments of the present disclosure will be described in detail with reference to the accompanying drawings. Like components are denoted by like reference numerals throughout the specification, and repeated descriptions thereof may be omitted.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

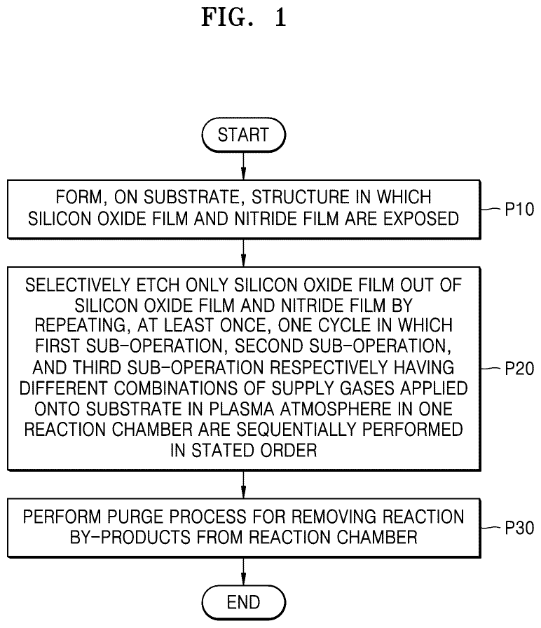

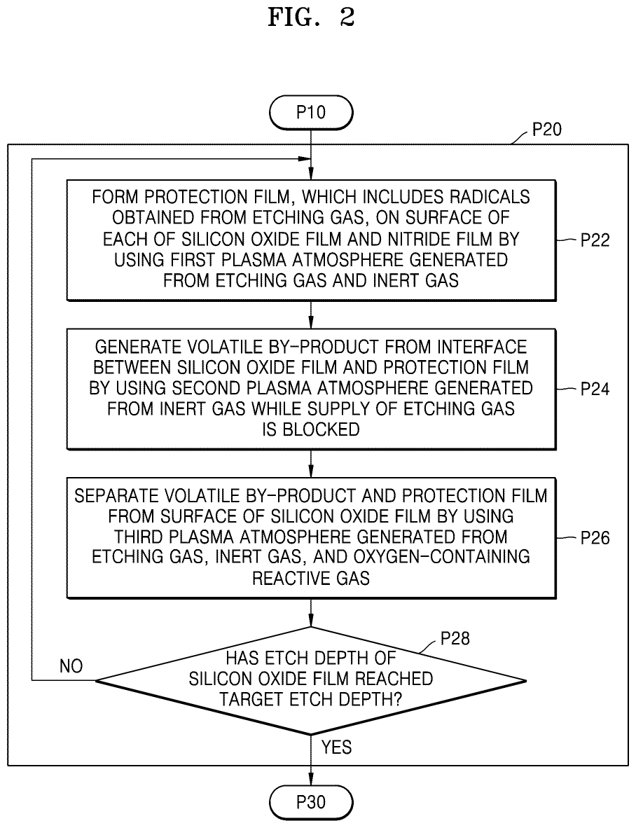

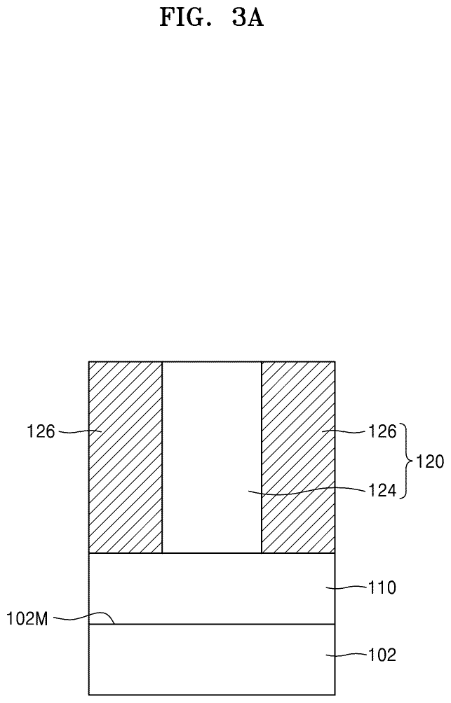

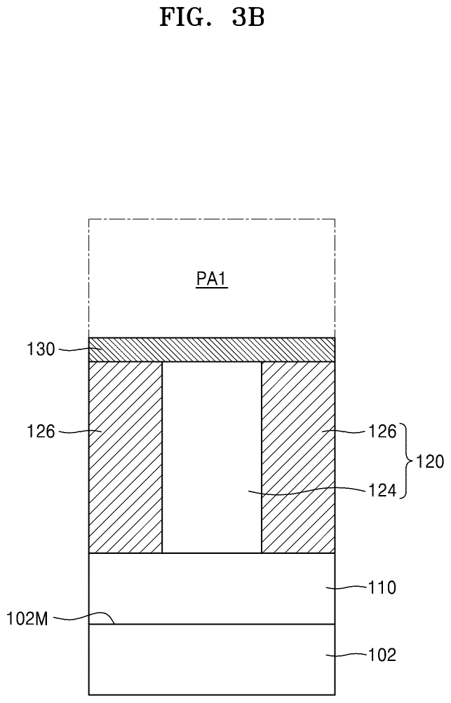

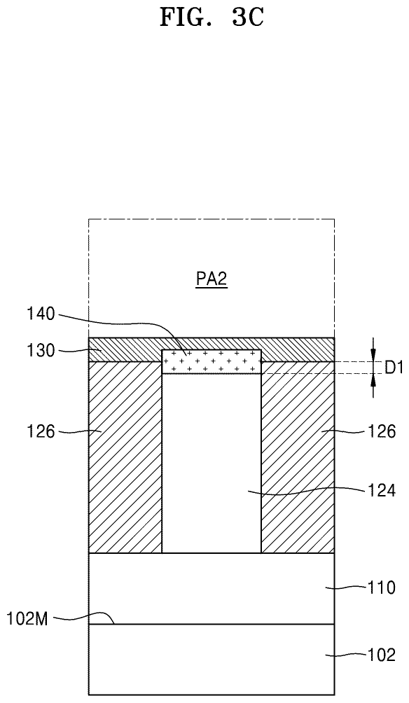

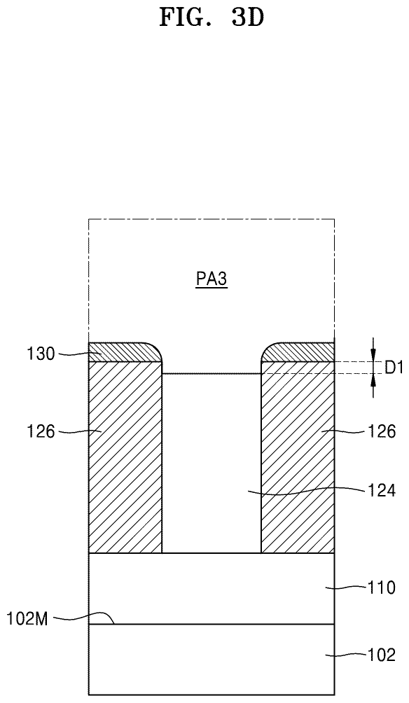

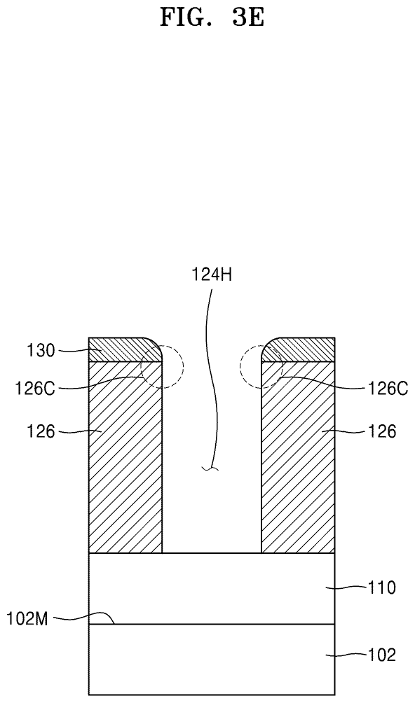

FIGS. 1 and 2 are flowcharts illustrating a method of manufacturing an integrated circuit device, according to embodiments. FIGS. 3A to 3E are cross-sectional views respectively illustrating a sequence of processes of a method of manufacturing an integrated circuit device, according to embodiments. A method of manufacturing an integrated circuit device, according to embodiments, is described with reference to FIGS. 1, 2, and 3A to 3E.

Referring to FIG. 1, in a process P10, a structure, in which a silicon oxide film and a nitride film are exposed, may be formed on a substrate. For example, to form the structure according to the process P10 of FIG. 1, as shown in FIG. 3A, a lower structure 110 may be formed on a main surface 102M (e.g., an upper surface) of a substrate 102, and an upper structure 120 including a silicon oxide film 124 and a nitride film 126 may be formed on the lower structure 110.

The substrate 102 may include an elemental semiconductor, such as Si or Ge, or a compound semiconductor, such as SiGe, SiC, GaAs, InAs, or InP. The substrate 102 may include a conductive region. The conductive region may include conductive structures each including an impurity-doped well, an impurity-doped semiconductor layer, a metal, a conductive metal nitride, or a combination thereof. In some embodiments, the lower structure 110 may include various conductive regions such, for example, a wiring layer, a contact plug, a transistor, and the like, and insulating patterns that insulate the conductive regions from each other.

The silicon oxide film 124 may include, but is not limited to, SiO₂, borosilicate glass (BSG), phosphosilicate glass (PSG), borophosphosilicate glass (BPSG), undoped silicate glass (USG), tetraethylorthosilicate glass (TEOS), or a combination thereof. The nitride film 126 may include a material film including silicon atoms and nitrogen atoms. For example, the nitride film 126 may include SiN, SiON, SiCON, SiBN, SiCN, or a combination thereof. As used herein, each of the terms “SiN”, “SiON”, “SiCON”, “SiBN”, and “SiCN” refers to a material including elements contained in each term and is not a chemical formula representing a stoichiometric relationship. In some embodiments, SiN may include a silicon nitride film including Si₃N₄.

After the upper structure 120 is formed, the silicon oxide film 124 and the nitride film 126 may be exposed. While the upper structure 120 including the silicon oxide film 124 and the nitride film 126 is being formed, the upper structure 120 may undergo various processes, such as dry cleaning, wet cleaning, dry etching, and wet etching. As a result, an amine group (−NH₂) may be exposed at the exposed surface of the nitride film 126, and a hydroxyl group (—OH) may be exposed at the exposed surface of the silicon oxide film 124. However, embodiments of the present disclosure are not limited thereto.

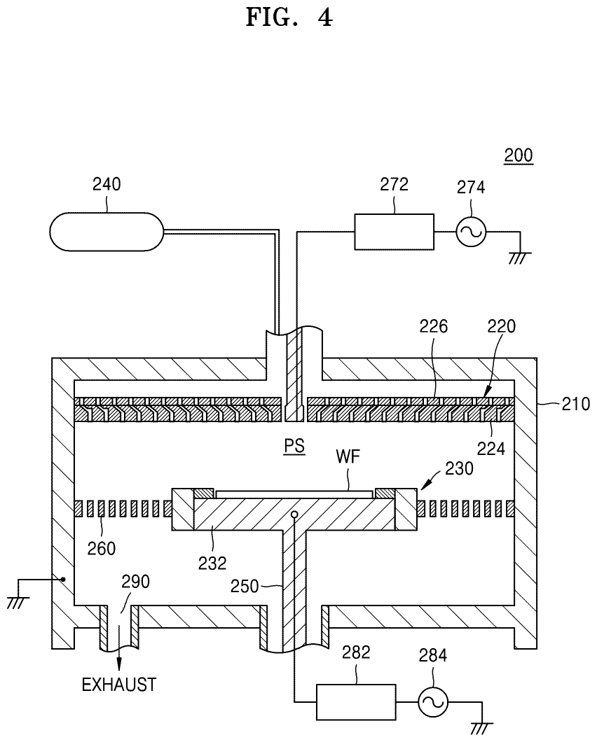

In a process P20 of FIG. 1, one cycle, in which a first sub-operation, a second sub-operation, and a third sub-operation respectively having different combinations of supply gases applied onto the substrate 102 are sequentially performed in the stated order in a reaction chamber (e.g., a reaction chamber 210 shown in FIG. 4), may be repeated at least once, thereby performing selective cycle etching for selectively etching only the silicon oxide film from among the silicon oxide film and the nitride film that are exposed in the structure formed in the process P10.

FIG. 4 is a diagram illustrating a schematic configuration of a plasma etching apparatus 200 that may be used to perform the selective cycle etching for selectively etching only the silicon oxide film from among the silicon oxide film and the nitride film according to the process P20 of FIG. 1. FIG. 4 illustrates a schematic longitudinal-sectional configuration of an etching apparatus of a capacitively-coupled plasma (CCP) type (e.g., a CCP etching apparatus). The plasma etching apparatus 200 may include the reaction chamber 210 in which an etching process may be performed on a wafer WF. The reaction chamber 210 may be grounded. In the reaction chamber 210, an upper electrode 220 and a lower electrode 230 may be arranged to face each other. The upper electrode 220 and the lower electrode 230 may constitute a pair of parallel flat-plate electrodes, and a plasma space PS may be provided between the upper electrode 220 and the lower electrode 230. The upper electrode 220 may include an electrode plate 224 adjacent to the plasma space PS, and a cooling plate 226 arranged at an opposite side of the upper electrode 220, away from the plasma space PS. Each of the electrode plate 224 and the cooling plate 226 may include a conductive material, such as silicon or aluminum. A plurality of through-holes may be formed in each of the electrode plate 224 and the cooling plate 226. An etching gas may be introduced from a gas supply source 240 into the plasma space PS in the reaction chamber 210 through the plurality of through-holes formed in each of the electrode plate 224 and the cooling plate 226.

The lower electrode 230 may include an electrostatic chuck 232 for holding the wafer WF. The electrostatic chuck 232 may include a metal, such as aluminum, and may be supported by a support member 250. An insulator may be arranged between the electrostatic chuck 232 and the support member 250. A baffle plate 260, in which micro-pores are formed, may be mounted around an outer circumference of the electrostatic chuck 232. The flow of a gas in the reaction chamber 210 may be controlled by the baffle plate 260. The baffle plate 260 may be grounded.

A radio-frequency (RF) power source 274 may be connected to the upper electrode 220 via a matcher 272. The RF power source 274 may apply source power at an intended frequency to the upper electrode 220. An RF power source 284 may be connected to the lower electrode 230 via a matcher 282. The RF power source 284 may apply bias power at an intended frequency to the lower electrode 230. The etching gas supplied from the gas supply source 240 into the reaction chamber 210 may be excited by the source power applied by the RF power source 274, and thus, plasma may be generated in the plasma space PS. An exhaust port 290 may be formed in a lower surface of the reaction chamber 210. An exhaust device may be connected to the exhaust port 290, and the inside of the reaction chamber 210 may be exhausted by the exhaust device, thereby maintaining the inside of the reaction chamber 210 in a vacuum state.

To perform the selective cycle etching according to the process P20 of FIG. 1, processes described below with reference to processes P22, P24, P26, and P28 shown in FIG. 2, or processes described below with reference to FIGS. 3B, 3C, and 3D may be sequentially performed at least once by using the plasma etching apparatus 200 shown in FIG. 4.

To perform the selective cycle etching according to the process P20 of FIG. 1, embodiments of the present disclosure are not limited to the plasma etching apparatus 200 of a CCP type shown in FIG. 4, and a plasma etching apparatus of an inductively coupled plasma (ICP) type may be used (e.g., an ICP etching apparatus).

An example of a method of performing the selective cycle etching according to the process P20 of FIG. 1 is described with reference to FIGS. 2, 3B, 3C, 3D, and 4.

Referring to FIGS. 2, 3B, and 4, in a process P22, to perform the first sub-operation of the selective cycle etching, the substrate 102 including thereon the structure, in which the silicon oxide film 124 and the nitride film 126 are exposed, may be arranged on the electrostatic chuck 232 in the reaction chamber 210 of the plasma etching apparatus 200. Next, each of the silicon oxide film 124 and the nitride film 126 may be exposed to a first plasma atmosphere PA1 generated from the etching gas and an inert gas, thereby forming a protection film 130, which includes radicals obtained from the etching gas, on the surface of each of the silicon oxide film 124 and the nitride film 126.

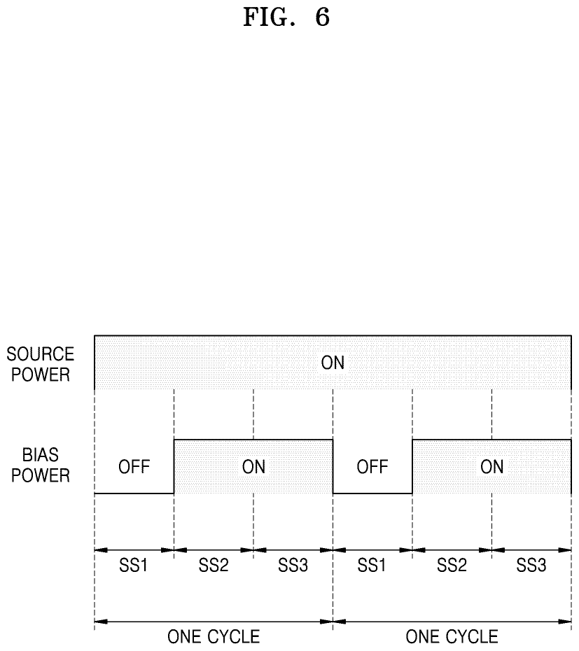

In some embodiments, the first sub-operation according to the process P22 may be performed under the condition that activated ions in the first plasma atmosphere PA1 generated from the etching gas and the inert gas irregularly move without particular directionality. An example of a method of forming the first plasma atmosphere PA1 is described below with reference to FIG. 6.

The etching gas may include at least one compound selected from among a hydrofluorocarbon and a perfluorocarbon. The hydrofluorocarbon may include an unsaturated compound including two to five carbon (C) atoms, at least one hydrogen (H) atom, and at least one fluorine (F) atom. In some embodiments, the hydrofluorocarbon may include an unsaturated compound represented by CₓH_{y}F_{z} (where 2≤x≤5, 1≤y≤9, and 1≤z≤9). For example, the hydrofluorocarbon may include, but is not limited to, C₃HF₅, C₃H₂F₄, or a combination thereof. The perfluorocarbon may include, but is not limited to, octafluorocyclopentene (C₅F₈).

In some embodiments, the etching gas may include a hydrofluorocarbon having a boiling point of 0° C. or less at atmospheric pressure. For example, the boiling point of the etching gas at atmospheric pressure may be less than 0° C. For example, C₃H₂F₄ has a boiling point of about −29° C., and C₃HF₅ has a boiling point of about −18° C. In the method of manufacturing an integrated circuit device according to embodiments, when the etching gas includes a hydrofluorocarbon having a boiling point of 0° C. or less at atmospheric pressure, the etching gas has excellent storage stability because the etching gas is not affected by an ambient environment, such as temperature or humidity, during the storage of the etching gas, and there is no need of a separate vaporizer to use the etching gas for an etching process. Therefore, manufacturing equipment of the integrated circuit device may be simplified. In addition, when the etching gas is supplied into the reaction chamber 210, because the etching gas may be supplied consistently in a vapor phase over time without being affected by the length of a supply tube, the process stability in the manufacturing process of the integrated circuit device may improve, and because the etching gas may be easily vaporized for reaction residue of the etching gas not to remain on a wafer surface in the reaction chamber 210 during the performance of an etching process using the etching gas, the yield of the manufacturing process of the integrated circuit device may improve.

In the first sub-operation according to the process P22, the inert gas may include Ar, He, or N₂.

The protection film 130 may include radicals obtained from the etching gas, for example, a gas including C₃HF₅, C₃H₂F₄, or a combination thereof. For example, the protection film 130 may include radicals having various structures including carbon (C) atoms, hydrogen (H) atoms, and/or fluorine (F) atoms.

Referring to FIGS. 2, 3C, and 4, in a process P24, to perform the second sub-operation of the selective cycle etching, a resulting product in which the protection film 130 is formed on the surface of each of the silicon oxide film 124 and the nitride film 126 may be exposed to a second plasma atmosphere PA2, which is generated from the inert gas, in the reaction chamber 210 of the plasma etching apparatus 200, thereby forming a volatile gas layer 140 including volatile by-products that are generated from an interface between the silicon oxide film 124 and the protection film 130 due to reaction between the silicon oxide film 124 and the protection film 130. For example, the volatile by-products of the volatile gas layer 140 may include, but are not limited to, CO₂, SiF₄, and the like.

After the volatile gas layer 140 is formed between the silicon oxide film 124 and the protection film 130, portions, which cover the silicon oxide film 124, of the protection film 130 may have relatively lower thicknesses than thicknesses of portions, which cover the nitride film 126, of the protection film 130.

While the second sub-operation is being performed, the supply of the etching gas into the reaction chamber 210 may be maintained blocked, and the second plasma atmosphere PA2 generated from a supply gas including only the inert gas may be used. In the second sub-operation according to the process P24, the inert gas may include Ar, He, or N₂.

While the second sub-operation is being performed according to the process P24, the volatile gas layer 140 may be maintained in a space between the silicon oxide film 124 and the protection film 130. After the volatile gas layer 140 is formed between the silicon oxide film 124 and the protection film 130, the upper surface of the silicon oxide film 124 may be lower by as much as a first thickness D1 than the upper surface of the silicon oxide film 124 before process P24 is performed on the silicon oxide film 124.

In some embodiments, the second sub-operation according to the process P24 may be performed under the condition that directionality in a direction perpendicular to the upper surface 102M of the substrate 102 is given to activated ions in the second plasma atmosphere PA2 generated from the inert gas. For example, in the second plasma atmosphere PA2, the inert gas, for example, activated ions obtained from Ar, may transfer ion energy to materials on or over the substrate 102. An example of a method of forming the second plasma atmosphere PA2 to give directionality to the activated ions is described below with reference to FIG. 6.

Referring to FIGS. 2, 3D, and 4, in a process P26, to perform the third sub-operation of the selective cycle etching, a resulting product in which the volatile gas layer 140 is formed may be exposed to a third plasma atmosphere PA3, which is generated from at least two gases including the inert gas and an oxygen-containing reactive gas from among the etching gas, the inert gas, and the oxygen-containing reactive gas, in the reaction chamber 210 of the plasma etching apparatus 200, thereby performing a flush process to separate the volatile by-products and the protection film 130 from the surface of the silicon oxide film 124. In some embodiments, the third plasma atmosphere PA3 may be generated from the etching gas, the inert gas, and the oxygen-containing reactive gas. In some embodiments, the third plasma atmosphere PA3 may be generated from the inert gas and the oxygen-containing reactive gas and may not include plasma generated from the etching gas. As a result, a portion, which covers the silicon oxide film 124, of the protection film 130 and the volatile by-products constituting the volatile gas layer 140 may be separated from and physically away from the silicon oxide film 124 to remain floating in the reaction chamber 210, and the upper surface of the silicon oxide film 124 having a thickness reduced by as much as the first thickness D1 may be exposed to the third plasma atmosphere PA3.

A detailed configuration of the etching gas used in the third sub-operation according to the process P26 may be substantially the same as that of the etching gas used when the first sub-operation according to the process P22 is performed. However, the flow rate of the etching gas used in the third sub-operation according to the process P26 may be less than the flow rate of the etching gas used in the first sub-operation according to the process P22. For example, the flow rate of the etching gas supplied into the reaction chamber 210 in the first sub-operation according to the process P22 may be selected from a range of about 5 sccm to about 30 sccm, and the flow rate of the etching gas supplied into the reaction chamber 210 in the third sub-operation according to the process P26 may be selected from a range of at least about 1 sccm and less than about 5 sccm, but embodiments of the present disclosure are not limited thereto.

The etching gas used in the first sub-operation according to the process P22 may include a material that is the same as or different from a material of the etching gas used in the third sub-operation according to the process P26. In some embodiments, the etching gas used in the first sub-operation according to the process P22 and the etching gas used in the third sub-operation according to the process P26 may include the same material selected from C₃HF₅ and C₃H₂F₄. In some embodiments, the etching gas used in the first sub-operation according to the process P22 and the etching gas used in the third sub-operation according to the process P26 may respectively include different materials selected from C₃HF₅ and C₃H₂F₄.

In the third sub-operation according to the process P26, the inert gas may include Ar, He, or N₂.

In the third sub-operation according to the process P26, the oxygen-containing reactive gas may include O₂.

While the third sub-operation according to the process P26 is being performed, carbon atoms constituting the protection film 130, which covers the silicon oxide film 124 and the nitride film 126, and oxygen radicals generated from the oxygen-containing reactive gas may react with each other in the plasma space PS of the reaction chamber 210 and generate CO₂. Accordingly, the protection film 130, which is apart from the silicon oxide film 124 with the volatile gas layer 140 therebetween, may be decomposed, and decomposition products thereof may be dispersed in the reaction chamber 210 so as to be away from the silicon oxide film 124.

On the other hand, because the portions, which cover the nitride film 126, of the protection film 130 have relatively higher thicknesses than the portions, which cover the silicon oxide film 124, of the protection film 130, even when carbon atoms in the portions, which cover the nitride film 126, of the protection film 130 undergo a process of reacting with the oxygen radicals generated from the oxygen-containing reactive gas to generate CO₂, a portion of the protection film 130 may still remain on the nitride film 126 after the portions, which cover the silicon oxide film 124, of the protection film 130 are completely removed through reaction. Therefore, the portions, which cover the nitride film 126, of the protection film 130 may at least partially remain on the nitride film 126, and portions, which remain on the nitride film 126, of the protection film 130 may protect the nitride film 126 during a subsequent process of additional etching of the silicon oxide film 124.

In some embodiments, the third sub-operation according to the process P26 may be performed under the condition that directionality in a direction perpendicular to the upper surface 102M of the substrate 102 is given to activated ions in the third plasma atmosphere PA3. An example of a method of forming the third plasma atmosphere PA3 to give directionality to the activated ions is described below with reference to FIG. 6.

In a process P28 of FIG. 2, after the third sub-operation according to the process P26 is performed, it may be determined whether the etch depth of the silicon oxide film 124 over the substrate 102 in the reaction chamber 210 has reached a target etch depth.

In the process P28 of FIG. 2, when it is determined that the etch depth of the silicon oxide film 124 has not reached the target etch depth, the first sub-operation according to the process P22, the second sub-operation according to the process P24, and the third sub-operation according to the process P26 may be further repeated in the stated order at least once.

In the process P28 of FIG. 2, the first sub-operation according to the process P22, the second sub-operation according to the process P24, and the third sub-operation according to the process P26 may be repeatedly performed in the stated order in the reaction chamber 210 without a purge process for removing reaction by-products remaining in the reaction chamber 210, such that the etch depth of the silicon oxide film 124 reaches the target etch depth. For example, the first sub-operation according to the process P22, the second sub-operation according to the process P24, and the third sub-operation according to the process P26 may be performed in the stated order about 5 times to about 30 times without a purge process for removing reaction by-products remaining in the reaction chamber 210, such that the etch depth of the silicon oxide film 124 reaches the target etch depth, but embodiments of the present disclosure are not limited thereto.

Each selective cycle etching including the first sub-operation according to the process P22, the second sub-operation according to the process P24, and the third sub-operation according to the process P26 may be performed at a temperature of about 10° C. to about 100° C., for example, a temperature of about 20° C. to about 90° C. or a temperature of about 40° C. to about 80° C., but embodiments of the present disclosure are not limited thereto.

Each selective cycle etching including the first sub-operation according to the process P22, the second sub-operation according to the process P24, and the third sub-operation according to the process P26 may be performed at a pressure of about 1 mTorr to about 100 mTorr, for example, a pressure of about 10 mTorr to about 50 mTorr or a pressure of about 20 mTorr to about 30 mTorr, but embodiments of the present disclosure are not limited thereto.

When it is determined in a process P28 of FIG. 2 that the etch depth of the silicon oxide film 124 has reached the target etch depth, the selective cycle etching for etching the silicon oxide film 124 may be terminated, and a purge process for removing reaction by-products from the reaction chamber 210 may be performed according to the process P30 of FIG. 1. After the purge process according to the process P30 of FIG. 1 is performed, the substrate 102 may be unloaded from the reaction chamber 210.

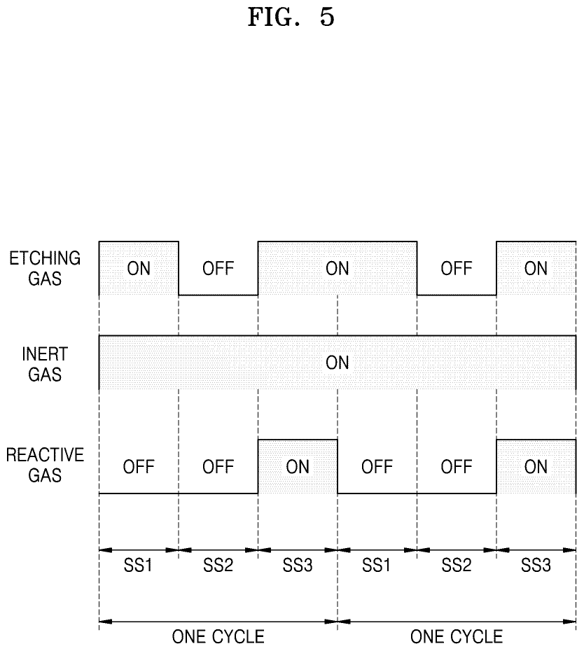

FIG. 5 is a timing pulse diagram illustrating the supply of a process gas for each sub-operation in a plurality of cycles each including a first sub-operation SS1 according to the process P22 of FIG. 2, a second sub-operation SS2 according to the process P24 of FIG. 2, and a third sub-operation SS3 according to the process P26 of FIG. 2. In FIG. 5, “ON” refers to supplying a gas corresponding to “ON” into the reaction chamber 210, and “OFF” refers to blocking a gas corresponding to “OFF” from being supplied into the reaction chamber 210.

Referring to FIG. 5, during one cycle, while the etching gas (i.e., “ETCHING GAS”) may be supplied into the reaction chamber 210 in each of the first sub-operation SS1 according to the process P22 and the third sub-operation SS3 according to the process P26, the etching gas may not be supplied into the reaction chamber 210 in the second sub-operation SS2 according to the process P24. During one cycle, the inert gas (i.e., “INERT GAS”) may be supplied into the reaction chamber 210 in each of the first sub-operation SS1 according to the process P22, the second sub-operation SS2 according to the process P24, and the third sub-operation SS3 according to the process P26. During one cycle, the oxygen-containing reactive gas (i.e., “REACTIVE GAS”) may not be supplied into the reaction chamber 210 in each of the first sub-operation SS1 according to the process P22 and the second sub-operation SS2 according to the process P24, and may be supplied into the reaction chamber 210 only in the third sub-operation SS3 according to the process P26.

FIG. 6 is a timing diagram illustrating the application or non-application of source power and bias power for each sub-operation in a plurality of cycles each including the first sub-operation SS1 according to the process P22, the second sub-operation SS2 according to the process P24, and the third sub-operation SS3 according to the process P26. In FIG. 6, “ON” refers to applying power corresponding to “ON” to the reaction chamber 210, and “OFF” refers to not applying power corresponding to “OFF” to the reaction chamber 210.

Referring to FIG. 6, in the first sub-operation SS1 according to the process P22, source power output from the RF power source 274 in the plasma etching apparatus 200 shown in FIG. 4 may be applied to the upper electrode 220 in the reaction chamber 210, thereby exciting the etching gas and the inert gas in the plasma space PS of the reaction chamber 210. Here, because the RF power source 284 does not apply bias power to the lower electrode 230, activated ions in the first plasma atmosphere PA1 generated from the etching gas and the inert gas, that is, radicals of each of the etching gas and the inert gas that are excited in the plasma space PS, may irregularly move without particular directionality.

In the second sub-operation SS2 according to the process P24, the source power output from the RF power source 274 in the plasma etching apparatus 200 shown in FIG. 4 may be applied to the upper electrode 220 in the reaction chamber 210, and the bias power output from the RF power source 284 may be applied to the lower electrode 230 in the reaction chamber 210, thereby exciting the inert gas in the plasma space PS of the reaction chamber 210. By doing this, activated ions in the second plasma atmosphere PA2 generated from the inert gas in the second sub-operation SS2 according to the process P24 may move toward the substrate 102 while having directionality in the direction perpendicular to the upper surface 102M of the substrate 102. In some embodiments, the source power applied to the upper electrode 220 in the second sub-operation SS2 according to the process P24 may be less than the source power applied to the upper electrode 220 in the first sub-operation SS1 according to the process P22.

In the third sub-operation SS3 according to the process P26, the source power output from the RF power source 274 in the plasma etching apparatus 200 shown in FIG. 4 may be applied to the upper electrode 220 in the reaction chamber 210, and the bias power output from the RF power source 284 may be applied to the lower electrode 230 in the reaction chamber 210, thereby exciting the etching gas, the inert gas, and the oxygen-containing reactive gas in the plasma space PS of the reaction chamber 210. By doing this, activated ions in the third plasma atmosphere PA3 generated from each of the etching gas, the inert gas, and the oxygen-containing reactive gas in the third sub-operation SS3 according to the process P26 may move toward the substrate 102 while having directionality in the direction perpendicular to the upper surface 102M of the substrate 102, thereby accelerating reaction between the protection film 130 and oxygen radicals generated from the oxygen-containing reactive gas. In some embodiments, the source power applied to the upper electrode 220 in the third sub-operation SS3 according to the process P26 may be less than the source power applied to the upper electrode 220 in the first sub-operation SS1 according to the process P22 and may be greater than the source power applied to the upper electrode 220 in the second sub-operation SS2 according to the process P24.

FIG. 3E illustrates an example of a resulting product in which a hole 124H is formed between a plurality of portions of the nitride film 126 to expose a portion of the lower structure 110 by etching the silicon oxide film 124 through a selective cycle etching process, in which the first sub-operation SS1 according to the process P22, the second sub-operation SS2 according to the process P24, and the third sub-operation SS3 according to the process P26 are sequentially performed in the stated order a plurality of times, according to the process P20 of FIGS. 1 and 2.

After the selective cycle etching for etching the silicon oxide film 124 is terminated, a process of removing the protection film 130 remaining on the nitride film 126 may be further performed. To remove the protection film 130 remaining on the nitride film 126, dry etching, wet etching, or a combination thereof may be used.

According to the method, described with reference to FIGS. 1 to 6, of manufacturing an integrated circuit device according to embodiments, while the silicon oxide film 124 is being etched to form the hole 124H between the plurality of portions of the nitride film 126, because each of the plurality of portions of the nitride film 126 is protected by the protection film 130, there is no concern that the plurality of portions of the nitride film 126 are consumed or damaged by an etching atmosphere of the silicon oxide film 124. In particular, in each of the plurality of portions of the nitride film 126, unintended consumption of a corner portion adjacent to the entrance of the hole 124H, as indicated by a dashed circle 126C in FIG. 3E, may be prevented. Therefore, according to the method of manufacturing an integrated circuit device according to embodiments, even while the silicon oxide film 124 and the nitride film 126 over the substrate 102 are simultaneously exposed, sufficient etch selectivity between the silicon oxide film 124 and the nitride film 126 may be secured, and the CD of each of the hole 124H and the plurality of portions of the nitride film 126, which remain over the substrate 102, may be strictly controlled. Therefore, the manufacturing process efficiency and reliability of an integrated circuit device may improve, and the dimensional precision of patterns may improve.

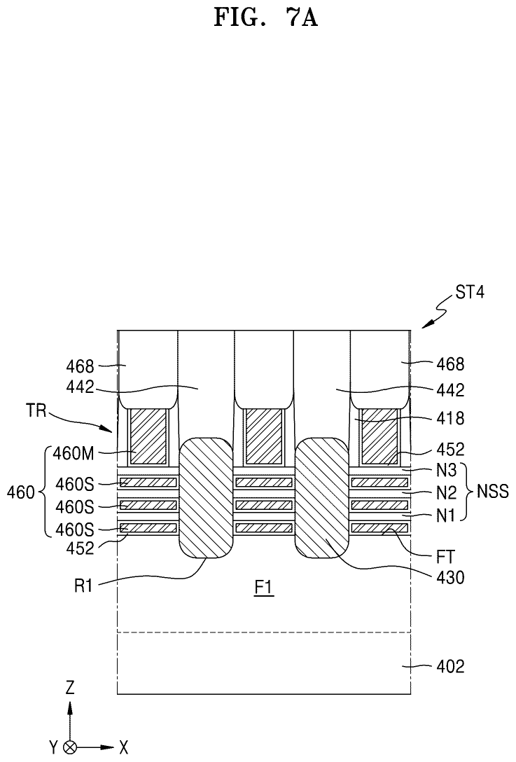

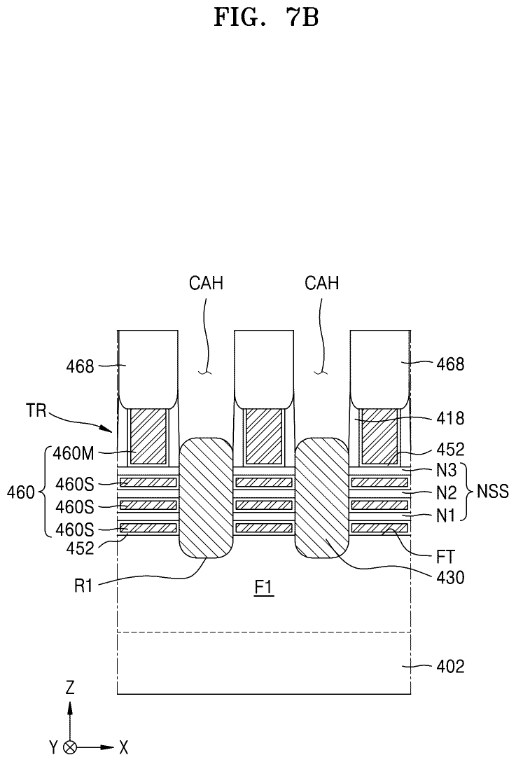

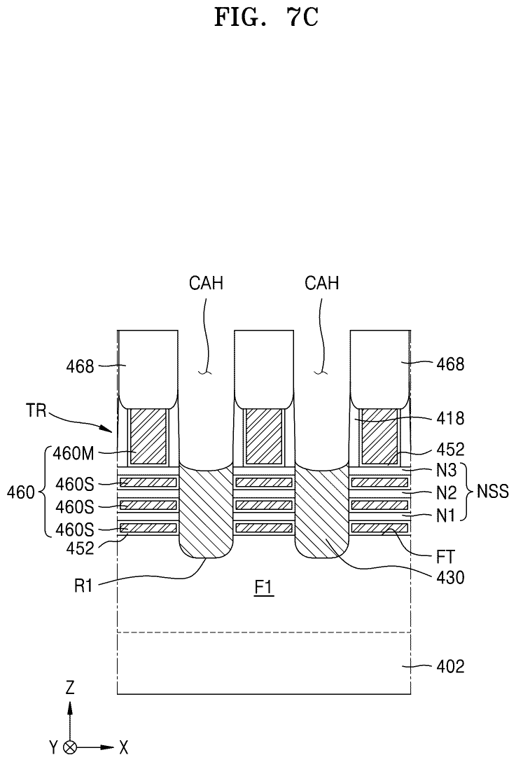

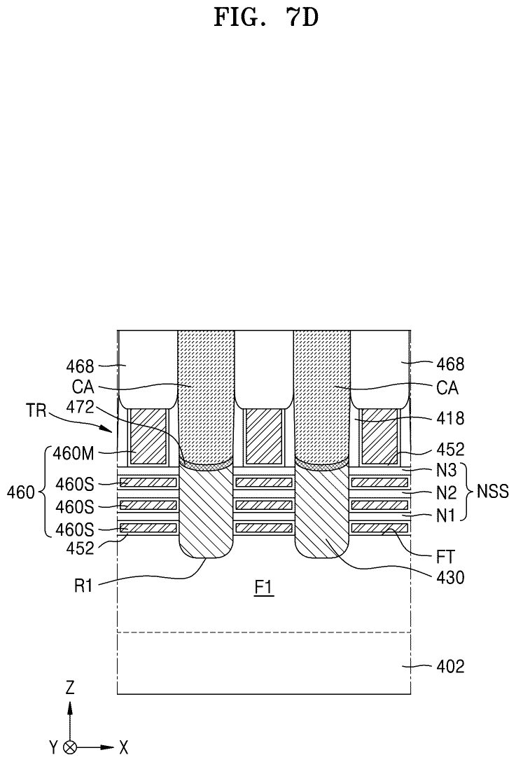

FIGS. 7A to 7D are cross-sectional views respectively illustrating a sequence of processes of a method of manufacturing an integrated circuit device, according to some embodiments.

A method of manufacturing an integrated circuit device is described with reference to FIGS. 7A to 7D. The integrated circuit device may include a transistor TR that has a gate-all-around structure including a nanowire or nanosheet-shaped active region and a gate surrounding the active region.

Referring to FIG. 7A, a plurality of transistors TR and a structure ST4 may be formed over (e.g., on) a substrate 402, the structure ST4 covering the plurality of transistors TR and including a silicon oxide film and a nitride film.

The structure ST4 may include the substrate 402, a fin-type active region F1 protruding from the substrate 402 and extending lengthwise in a first horizontal direction (e.g., an X direction), and a plurality of nanosheet stacks NSS arranged apart from the fin-type active region F1 in a vertical direction (e.g., a Z direction) to face a fin top surface FT of the fin-type active region F1. As used herein, the term “nanosheet” refers to a conductive structure having a cross-section that is substantially perpendicular to a current-flowing direction. The nanosheet may also be understood as including a nanowire.

Each of the plurality of nanosheet stacks NSS may include at least one nanosheet arranged apart from the fin top surface FT of the fin-type active region F1 in the vertical direction (e.g., the Z direction) to face the fin top surface FT of the fin-type active region F1. In some embodiments, each of the plurality of nanosheet stacks NSS may include a first nanosheet N1, a second nanosheet N2, and a third nanosheet N3, which overlap with each other in the vertical direction (e.g., the Z direction), over the fin-type active region F1.

A plurality of gate lines 460 may be arranged over the fin-type active region F1. Each of the plurality of gate lines 460 may extend lengthwise in a second horizontal direction (e.g., a Y direction) intersecting with the first horizontal direction (e.g., the X direction). The plurality of nanosheet stacks NSS may be respectively arranged over the fin top surface FT of the fin-type active region F1 in intersection areas between the fin-type active region F1 and the plurality of gate lines 460. Each of the plurality of gate lines 460 may surround the first nanosheet N1, the second nanosheet N2, and the third nanosheet N3, which are included in a nanosheet stack NSS.

Each of the plurality of gate lines 460 may include a main gate portion 460M and a plurality of sub-gate portions 460S. The main gate portion 460M may extend lengthwise in the second horizontal direction (e.g., the Y direction) to cover an upper surface of the nanosheet stack NSS. The plurality of sub-gate portions 460S may be integrally connected to the main gate portion 460M and may be respectively arranged one-by-one between the first nanosheet N1, the second nanosheet N2, and the third nanosheet N3 and between the first nanosheet N1 and the fin-type active region F1.

A plurality of recesses R1 may be formed in the fin-type active region F1. A plurality of source/drain regions 430 may be respectively arranged in the plurality of recesses R1. Each of the plurality of source/drain regions 430 may be arranged between a pair of gate lines 460 from among the plurality of gate lines 460. Each of the plurality of source/drain regions 430 may be in contact with the first nanosheet N1, the second nanosheet N2, and the third nanosheet N3 of the nanosheet stack NSS adjacent thereto.

Each of the plurality of gate lines 460 may include a metal, a metal nitride, a metal carbide, or a combination thereof. The metal may be selected from Ti, W, Ru, Nb, Mo, Hf, Ni, Co, Pt, Yb, Tb, Dy, Er, and Pd. The metal nitride may be selected from TiN and TaN. The metal carbide may include TiAlC. Each of the plurality of gate lines 460 may further include a gap-fill metal film. The gap-fill metal film may include a W film or an Al film. In some embodiments, each of the plurality of gate lines 460 may include, but is not limited to, a TiN film, a stack structure of TiAlC/TiN/W, a stack structure of TiN/TaN/TiAlC/TiN/W, or a stack structure of TiN/TaN/TiN/TiAlC/TiN/W.

A gate dielectric film 452 may be arranged between the nanosheet stack NSS and a gate line 460. The gate dielectric film 452 may be in contact with a lower surface and both sidewalls of the gate line 460 adjacent thereto. The gate dielectric film 452 may include a stack structure of an interface dielectric film and a high-k film. The interface dielectric film may include a low-k material film having a dielectric constant of about 9 or less, for example, a silicon oxide film, a silicon oxynitride film, or a combination thereof. In some embodiments, the interface dielectric film may be omitted. The high-k film may include a material having a dielectric constant that is greater than a dielectric constant of a silicon oxide film. For example, the high-k film may have a dielectric constant of about 10 to about 25. The high-k film may include, but is not limited to, hafnium oxide.

Either sidewall of the gate line 460 may be covered by an insulating spacer 418. The insulating spacer 418 may be arranged on the upper surface of each of the plurality of nanosheet stacks NSS to cover either sidewall of the main gate portion 460M. The insulating spacer 418 may be apart from the gate line 460 with the gate dielectric film 452 therebetween. The upper surface of each of the gate dielectric film 452, the gate line 460, and the insulating spacer 418 may be covered by a capping insulating pattern 468. The capping insulating pattern 468 may be in contact with the upper surface of each of the gate dielectric film 452, the gate line 460, and the insulating spacer 418. Each of the insulating spacer 418 and the capping insulating pattern 468 may include a nitride film. In some embodiments, each of the insulating spacer 418 and the capping insulating pattern 468 may include SiN, SiON, SiCON, SiBN, SiCN, or a combination thereof.

Both sidewalls of each of the plurality of sub-gate portions 460S may each be apart from a source/drain region 430 with the gate dielectric film 452 therebetween. The gate dielectric film 452 may be arranged between a sub-gate portion 460S of the gate line 460 and each of the first nanosheet N1, the second nanosheet N2, and the third nanosheet N3 and between the sub-gate portion 460S of the gate line 460 and the source/drain region 430.

The plurality of transistors TR may be respectively formed on the substrate 402 in the intersection areas between the fin-type active region F1 and the plurality of gate lines 460. Each of the first nanosheet N1, the second nanosheet N2, and the third nanosheet N3 of the nanosheet stack NSS may provide a channel region. In some embodiments, each of the first nanosheet N1, the second nanosheet N2, and the third nanosheet N3 of the nanosheet stack NSS may include a Si layer, a SiGe layer, or a combination thereof.

The plurality of source/drain regions 430 may be covered by an inter-gate dielectric 442. The inter-gate dielectric 442 may include a silicon oxide film. As shown in FIG. 7A, after the structure ST4 is formed over the substrate 402, the inter-gate dielectric 442 including a silicon oxide film and the capping insulating pattern 468 including a nitride film may be exposed at the upper surface of the structure ST4.

Referring to FIG. 7B, while the inter-gate dielectric 442 and the capping insulating pattern 468 over the substrate 102 are exposed, a selective cycle etching process may be performed to selectively etch only the inter-gate dielectric 442 from among the inter-gate dielectric 442 and the capping insulating pattern 468 in a plasma atmosphere by using an etching gas including a hydrofluorocarbon, thereby forming a hole CAH through the inter-gate dielectric 442 to expose the source/drain region 430 that is a portion of each of the plurality of transistors TR.

According to an embodiment, before the process described with reference to FIG. 7B is performed, a mask pattern may be formed to cover portions of the inter-gate dielectric 442, which are to remain over the substrate 402, thereby etching only a portion of the inter-gate dielectric 442 and forming the hole CAH through the inter-gate dielectric 442.

As shown in FIG. 7B, to selectively etch the inter-gate dielectric 442 from among the inter-gate dielectric 442 and the capping insulating pattern 468, the processes described with reference to FIGS. 1 to 6 may be performed. That is, to perform a selective cycle etching process for selectively etching only the inter-gate dielectric 442 from among the inter-gate dielectric 442 and the capping insulating pattern 468, one cycle of performing the first sub-operation, the second sub-operation, and the third sub-operation in the stated order may be repeated a plurality of times, the first sub-operation, the second sub-operation, and the third sub-operation respectively having different combinations of process gases applied onto the substrate 402 in a reaction chamber (e.g., the reaction chamber 210 shown in FIG. 4).

In the first sub-operation, the same or similar to the process P22 described with reference to FIGS. 2 and 3B, the protection film 130, which includes radicals obtained from the hydrofluorocarbon, may be formed on the surface of each of the inter-gate dielectric 442 and the capping insulating pattern 468 by using the first plasma atmosphere generated from the etching gas and the inert gas.

In the second sub-operation, the same or similar to the process P24 described with reference to FIGS. 2 and 3C, the volatile gas layer 140 may be formed by using the second plasma atmosphere generated from the inert gas while the etching gas is blocked from being supplied to the reaction chamber, the volatile gas layer 140 including volatile by-products generated from an interface between the inter-gate dielectric 442 and the protection film 130 due to reaction between the silicon oxide film constituting the inter-gate dielectric 442 and the protection film 130.

In the third sub-operation, the same or similar to the process P26 described with reference to FIGS. 2 and 3D, the volatile by-products and the protection film 130 may be separated from the surface of the silicon oxide film by using the third plasma atmosphere generated from at least two gases that include the inert gas and an oxygen-containing reactive gas from among the etching gas, the inert gas, and the oxygen-containing reactive gas.

While the third sub-operation is being performed, because portions, which cover the capping insulating pattern 468, of the protection film 130 have relatively higher thicknesses than portions, which cover the inter-gate dielectric 442, of the protection film 130, even when carbon atoms in the portions, which cover the capping insulating pattern 468, of the protection film 130 undergo a process of reacting with the oxygen radicals generated from the oxygen-containing reactive gas to generate CO₂, a portion of the protection film 130 may still remain on the capping insulating pattern 468 after the portions, which cover the inter-gate dielectric 442, of the protection film 130 are completely removed through reaction. Portions, which remain on the capping insulating pattern 468, of the protection film 130 may protect the capping insulating pattern 468 during a subsequent process of additional etching of the inter-gate dielectric 442.

The first sub-operation according to the process P22, the second sub-operation according to the process P24, and the third sub-operation according to the process P26 may be repeated in the stated order a plurality of times without a purge process for removing reaction by-products remaining in the reaction chamber 210, such that the source/drain region 430 is exposed by as much as a depth of the hole CAH. After the source/drain region 430 is exposed by as much as depth of the hole CAH, the selective cycle etching process may be terminated. In the selective cycle etching process described above, specific process gases and specific process conditions in each of the first sub-operation, the second sub-operation, and the third sub-operation may be the same as those described above with reference to FIGS. 1 to 6.

Referring to FIG. 7C, in the resulting product of FIG. 7B, a portion of the source/drain region 430 may be etched through the hole CAH, thereby enlarging the vertical-direction (e.g., Z-direction) size of the hole CAH. Therefore, a lower portion of the hole CAH may pass through an upper portion of the source/drain region 430.

Referring to FIG. 7D, in the resulting product of FIG. 7C, a plurality of metal silicide films 472, which respectively cover surfaces of the plurality of source/drain regions 430 exposed by a plurality of holes CAH, and a plurality of source/drain contacts CA, which are respectively arranged on the plurality of metal silicide films 472 to fill the holes CAH, may be formed.

Each of the plurality of source/drain contacts CA may be configured to be electrically connected to the source/drain region 430 via a metal silicide film 472. Each of the plurality of source/drain contacts CA may be apart from the main gate portion 460M of the gate line 460 in the first horizontal direction (e.g., the X direction) with the insulating spacer 418 therebetween.

Each of the plurality of source/drain contacts CA may include a conductive barrier film and a contact plug, which are sequentially stacked in the stated order on the metal silicide film 472. The conductive barrier film may surround a lower surface and a sidewall of the contact plug. In some embodiments, the conductive barrier film may include a metal or a metal nitride. For example, the conductive barrier film may include Ti, Ta, W, TiN, TaN, WN, WCN, TiSiN, TaSiN, WSiN, or a combination thereof. The contact plug may include a metal selected from molybdenum (Mo), copper (Cu), tungsten (W), cobalt (Co), ruthenium (Ru), manganese (Mn), titanium (Ti), tantalum (Ta), aluminum (Al), and a combination thereof.

According to the method, described with reference to FIGS. 7A to 7D, of manufacturing an integrated circuit device, while the inter-gate dielectric 442 is being etched to form the hole CAH between the plurality of capping insulating patterns 468, because each of the plurality of capping insulating patterns 468 is protected by the protection film 130, there is no concern that the plurality of capping insulating patterns 468 are consumed or damaged by an etching atmosphere of the inter-gate dielectric 442, and a corner portion, which is adjacent to the entrance of the hole CAH shown in FIG. 7B, in each of the plurality of capping insulating patterns 468 may be prevented from being unintentionally consumed. Therefore, according to the method, described with reference to FIGS. 7A to 7D, of manufacturing an integrated circuit device, even while the inter-gate dielectric 442 and the capping insulating pattern 468 over the substrate 402 are simultaneously exposed, sufficient etch selectivity between the inter-gate dielectric 442 and the capping insulating pattern 468 may be secured, and the CD of each of the hole CAH and the plurality of capping insulating patterns 468, which remain over the substrate 402, may be strictly controlled. Therefore, the manufacturing process efficiency and reliability of an integrated circuit device may improve, and the dimensional precision of patterns may improve.

According to an embodiments of the present disclosure, a system for manufacturing an integrated circuit device may be provided. The system may include a plasma etching apparatus (e.g., the plasma etching apparatus 200 of FIG. 4), and a controller configured to control the plasma etching apparatus to perform the method described with reference to FIGS. 1-7D.

For example, the controller may be configured to control components of the plasma etching apparatus 200, including, but not limited to, one or more (e.g., some or all) from among the gas supply source 240, the matcher 272, the RF power source 274, the matcher 282, and the RF power source 284, to perform the method described with reference to FIGS. 1-7D.

According to an embodiment, the controller may include at least one processor and memory storing computer instructions. The computer instructions may be configured to, when executed by the at least one processor, cause the controller to perform its functions.

According to an embodiment, the controller may be provided in or external to the plasma etching apparatus 200.

Next, evaluation examples of a method of manufacturing an integrated circuit device, according to embodiments, are described.

### Evaluation Example

Specimens, in which a silicon oxide (SiO₂) film and a silicon nitride (Si₃N₄) film on or over a substrate are exposed, underwent an etching process for selectively etching the silicon oxide film under reaction conditions shown below in Table 1 by using, as an etching gas, each of C₃H₂F₄ (CF₃—CF═CH₂, CF₃—CH═CHF), C₃HF₅ (CF₃—CF═CHF, CF₃—CH═CF₂, CHF₂—CF═CF₂), C₅F₈(CF₃—CF═CF—CF═CF₂, cyclic-C₅F₈), and C₄F₆ (CF₂═CF—CF═CF₂). In the present evaluation example, Ar was used as an inert gas and O₂ was used as an oxygen-containing reactive gas.

TABLE 1

1 cycle

| | | SS1 | SS2 | SS3 |
|---|---|---|---|---|
| Flow rate | Etching gas | 4-10 | 0 | 4 |
| (sccm) | O₂ | 0 | 0 | 4 |
| | Ar | 700 | 700 | 700 |
| Time (seconds) | | 8-10 | 8 | 4-8 |
| Power (W) | Source power | 400 | 50 | 100 |
| | Bias power | 0 | 100 | 100 |
| Temperature | Inner wall of | 80 | | |
| (° C.) | reaction | | | |
| | chamber | | | |
| | Electrostatic | 40 | | |
| | chuck | | | |

| | |
|---|---|
| Pressure (mTorr) | 25 |

In the present evaluation example, to selectively etch the silicon oxide film, by taking, as one cycle, the first sub-operation SS1 according to the process P22 of FIG. 2, the second sub-operation SS2 according to the process P24 of FIG. 2, and the third sub-operation SS2 according to the process P26 of FIG. 2, a selective cycle etching process was performed in a total of 7 cycles.

For each of the etching gas C₃H₂F₄ and the etching gas C₃HF₅, the flow rate of the etching gas was consistently set to 8 sccm in the first sub-operation SS1, and after a total of 7 cycles of the selective cycle etching process were completed for each of a process time of 8 seconds and a process time of 10 seconds for the first sub-operation SS1, the etch amount (i.e., TE in Table 2) of the silicon oxide film and the thickness (i.e., TD in Table 2) of a protection film deposited on the silicon oxide film were evaluated.

For the etching gas C₅F₈, the flow rate of the etching gas was consistently set to 8 sccm in the first sub-operation SS1, and after a total of 7 cycles of the selective cycle etching process were completed when the process time of the first sub-operation SS1 was set to 8 seconds, the etch amount (that is, TE) of the silicon oxide film and the thickness (i.e., TD) of a protection film deposited on the silicon oxide film were evaluated.

For the etching gas C₄F₆, the process time of the first sub-operation SS1 was consistently set to 8 seconds, and after a total of 7 cycles of the selective cycle etching process were completed for each of the flow rates of 4 sccm, 8 sccm, and 10 sccm for the etching gas in the first sub-operation SS1, the etch amount (i.e., TE) of the silicon oxide film and the thickness (i.e., TD) of a protection film deposited on the silicon oxide film were evaluated.

Results of the evaluation are shown below in Table 2.

TABLE 2

| | | | Flow rate | | | |
|---|---|---|---|---|---|---|
| | | Process | of etching | Process | | |
| | | time | gas | time | | |
| | Etching | of SS1 | in SS1 | of SS3 | TE | TD |
| Example | gas | (seconds) | (sccm) | (seconds) | (nm) | (nm) |
| Example 1 | C₃H₂F₄(yf) | 10 | 8 | 8 | 272 | 92 |
| Example 2 | C₃H₂F₄(yf) | 8 | 8 | 8 | 231 | 62 |
| Example 3 | C₃HF₅(ye) | 10 | 8 | 8 | 337 | 44 |
| Example 4 | C₃HF₅(ye) | 8 | 8 | 8 | 283 | 0 |
| Example 5 | C₅F₈ | 8 | 8 | 8 | 258 | 3 |
| Example 6 | C₃H₂F₄(ze) | 8 | 8 | 8 | 230 | 59 |
| Example 7 | C₃HF₅(yc) | 6 | 8 | 4 | 215 | 11 |
| Example 8 | C₃HF₅(yc) | 6 | 10 | 6 | 230 | 6 |
| Example 9 | C₃HF₅(zc) | 6 | 10 | 4 | 226 | 26 |
| Example 10 | C₃HF₅(zc) | 6 | 10 | 6 | 238 | 2 |
| Comparison | C₄F₆ | 8 | 4 | 8 | 267 | 0 |
| Example 1 | | | | | | |
| Comparison | C₄F₆ | 8 | 8 | 8 | −14 | 54 |
| Example 2 | | | | | | |
| Comparison | C₄F₆ | 8 | 10 | 8 | −66 | 100 |
| Example 3 | | | | | | |
| Comparison | C₄F₆ | 6 | 8 | 4 | −16 | 52 |
| Example 4 | | | | | | |
| Comparison | C₄F₆ | 6 | 10 | 4 | −47 | 62 |
| Example 5 | | | | | | |
| Comparison | C₄F₆ | 6 | 10 | 6 | −43 | 60 |
| Example 6 | | | | | | |

In Table 2, the structure of C₃H₂F₄(yf) is CF₃—CF═CH₂, the structure of C₃H₂F₄(ze) is CF₃—CH═CHF, the structure of C₃HF₅(ye) is CF₃—CF═CHF, the structure of C₃HF₅(yc) is CHF₂—CF═CF₂, and the structure of C₃HF₅(zc) is CF₃—CH═CF₂. The structure of C₅F₈ is CF₃—CF═CF—CF═CF₂, and the same result was obtained even when cyclic-C₅F₈ was used.

In the results of Table 2, in Example 4, after the selective cycle etching process is completed, there is no protection film deposited on the silicon nitride film, and even the etch amount of the silicon nitride film is 0 nm. In Comparison Example 1, after the selective cycle etching process is completed, there is no protection film deposited on the silicon nitride film, and the etch amount of the silicon nitride film is 1 nm.

From the results of Table 2, it may be seen that, in Examples 1 to 5 each using C₃H₂F₄, C₃HF₅, or C₅F₈ as the etching gas, the etching efficiency of the silicon oxide film is good while the silicon nitride film is effectively protected. In particular, in Examples 1 to 4 in which C₃H₂F₄ (boiling point equals about −29° C.) or C₃HF₅ (boiling point equals about −18° C.) having a boiling point less than 0° C. at atmospheric pressure was used as the etching gas, it may be seen that the protection film is deposited to a sufficient thickness on the silicon nitride film and thus more effectively protects the silicon nitride, and that the etching efficiency of the silicon oxide film is better because the silicon oxide film has a high etch amount for the same etching time.

On the other hand, referring to the results of Table 2 regarding Comparison Examples 1, 2, and 3 using C₄F₆ as the etching gas, it may be seen that, in Comparison Example 1, the silicon nitride film is consumed while no protection film is deposited on the silicon nitride film, and in Comparison Examples 2 and 3, the etching efficiency of the silicon oxide film is extremely deteriorated even though the protection film is deposited on the silicon nitride film to have a sufficient thickness to protect the silicon nitride film.

While non-limiting example embodiments of the present disclosure have been particularly described above with reference to the accompanying drawings, it will be understood that various changes in form and details may be made therein without departing from the spirit and scope of the present disclosure.

What is claimed is:

1. A method of manufacturing an integrated circuit device, the method comprising:
forming, on a substrate, a structure including a silicon oxide film and a nitride film; and
performing selective cycle etching that selectively etches only the silicon oxide film from among the silicon oxide film and the nitride film in a plasma atmosphere by using an etching gas including at least one compound selected from among a hydrofluorocarbon and a perfluorocarbon,
wherein the performing the selective cycle etching comprises repeating, at least once, one cycle including a first sub-operation, a second sub-operation after the first sub-operation, and a third sub-operation after the second sub-operation, wherein the first sub-operation, the second sub-operation, and the third sub-operation include applying respective, different combinations of supply gases onto the substrate in a reaction chamber,
wherein the first sub-operation comprises using a first plasma atmosphere obtained from the etching gas and an inert gas,
wherein the second sub-operation comprises using a second plasma atmosphere obtained from the inert gas while the etching gas is blocked from being supplied to the reaction chamber, and
wherein the third sub-operation comprises using a third plasma atmosphere obtained from at least two gases comprising the inert gas and an oxygen-containing reactive gas.

2. The method of claim 1, wherein the etching gas includes the hydrofluorocarbon, and the hydrofluorocarbon includes a boiling point of 0° C. or less at atmospheric pressure.

3. The method of claim 1, further comprising, after the selective cycle etching is finished, performing removing, by a purge process, reaction by-products from the reaction chamber,
wherein the performing the selective cycle etching comprises sequentially repeating the first sub-operation, the second sub-operation, and the third sub-operation in the stated order a plurality of times without a process of removing the reaction by-products from the reaction chamber, until the selective cycle etching is finished.

4. The method of claim 1, wherein the etching gas includes an unsaturated compound represented by CₓH_{y}F_{z}, where 2≤x≤5, 1≤y≤9, and 1≤z≤9.

5. The method of claim 1, wherein the etching gas includes C₃HF₅ or C₃H₂F₄.

6. The method of claim 1, wherein, in the third sub-operation, the oxygen-containing reactive gas includes O₂.

7. The method of claim 1, wherein the first sub-operation comprises forming a protection film on a surface of each of the silicon oxide film and the nitride film by exposing each of the silicon oxide film and the nitride film to the first plasma atmosphere obtained from the etching gas and the inert gas, wherein the protection film includes radicals obtained from the etching gas,
wherein the second sub-operation comprises forming a volatile gas layer by exposing a first resulting product having undergone the first sub-operation to the second plasma atmosphere obtained from the inert gas, wherein the volatile gas layer includes volatile by-products obtained from an interface between the silicon oxide film and the protection film due to a reaction between the silicon oxide film and the protection film, and
wherein the third sub-operation comprises separating the volatile by-products and the protection film from the surface of the silicon oxide film by exposing a second resulting product having undergone the second sub-operation to the third plasma atmosphere obtained from the at least two gases comprising the inert gas and the oxygen-containing reactive gas.

8. The method of claim 1, wherein the first sub-operation is performed under a condition that activated ions in the first plasma atmosphere irregularly move without particular directionality,
wherein the second sub-operation is performed under a condition that activated ions in the second plasma atmosphere have directionality in a direction perpendicular to an upper surface of the substrate, and
wherein the third sub-operation is performed under a condition that activated ions in the third plasma atmosphere have directionality in the direction perpendicular to the upper surface of the substrate.

9. The method of claim 1, wherein the nitride film includes SiN, SiON, SiCON, SiBN, SiCN, or a combination thereof.

10. The method of claim 1, wherein the first sub-operation comprises forming the first plasma atmosphere while applying first source power to an upper electrode in the reaction chamber and applying no bias power to a lower electrode in the reaction chamber,
wherein the second sub-operation comprises forming the second plasma atmosphere while applying second source power, which is less than the first source power, to the upper electrode, and applying first bias power to the lower electrode, and
wherein the third sub-operation comprises forming the third plasma atmosphere while applying third source power, which is less than the first source power and greater than the second source power, to the upper electrode, and applying second bias power to the lower electrode.

11. The method of claim 1, wherein the first sub-operation comprises supplying the etching gas into the reaction chamber at a first flow rate, and
wherein the third sub-operation comprises supplying the etching gas into the reaction chamber at a second flow rate that is less than the first flow rate.

12. The method of claim 1, wherein the selective cycle etching is performed at a temperature of 10° C. to 100° C.

13. A method of manufacturing an integrated circuit device, the method comprising:
forming, on a substrate, a transistor and a structure that is on the transistor, the structure including a silicon oxide film and a nitride film; and
forming, while the silicon oxide film and the nitride film on the substrate are exposed, a hole that exposes a portion of the transistor through the silicon oxide film, the forming comprising performing selective cycle etching that selectively etches only the silicon oxide film from among the silicon oxide film and the nitride film in a plasma atmosphere by using an etching gas including a hydrofluorocarbon,
wherein the performing the selective cycle etching comprises repeating, at least once, one cycle including a first sub-operation, a second sub-operation after the first sub-operation, and a third sub-operation after the second sub-operation, wherein the first sub-operation, the second sub-operation, and the third sub-operation include applying respective, different combinations of supply gases onto the substrate in a reaction chamber,
wherein the first sub-operation comprises forming a protection film on a surface of each of the silicon oxide film and the nitride film by using a first plasma atmosphere obtained from the etching gas and an inert gas, wherein the protection film includes radicals obtained from the hydrofluorocarbon,
wherein the second sub-operation comprises forming a volatile gas layer by a second plasma atmosphere obtained from the inert gas while the etching gas is blocked from being supplied to the reaction chamber, the volatile gas layer including volatile by-products obtained from an interface between the silicon oxide film and the protection film due to a reaction between the silicon oxide film and the protection film, and
wherein the third sub-operation comprising separating the volatile by-products and the protection film from the surface of the silicon oxide film by a third plasma atmosphere obtained from at least two gases comprising the inert gas and an oxygen-containing reactive gas.

14. The method of claim 13, wherein the etching gas includes an unsaturated compound having a boiling point of 0° C. or less at atmospheric pressure and represented by CₓH_{y}F_{z}, where 2≤x≤5, 1≤y≤9, and 1≤z≤9.

15. The method of claim 13, wherein the etching gas includes C₃HF₅ or C₃H₂F₄, and
wherein the oxygen-containing reactive gas includes O₂.

16. The method of claim 13, wherein the first sub-operation is performed under a condition that activated ions in the first plasma atmosphere irregularly move without particular directionality,
wherein the second sub-operation is performed under a condition that activated ions in the second plasma atmosphere have directionality in a direction perpendicular to an upper surface of the substrate, and
wherein the third sub-operation is performed under a condition that activated ions in the third plasma atmosphere have directionality in the direction perpendicular to the upper surface of the substrate.

17. The method of claim 13, wherein the nitride film includes SiN, SiON, SiCON, SiBN, or SiCN.

18. The method of claim 13, wherein the structure includes:
a fin-type active region extending lengthwise in a first horizontal direction on the substrate;
a pair of nanosheet stacks apart from a fin top surface of the fin-type active region in a vertical direction, the pair of nanosheet stacks facing the fin top surface of the fin-type active region, and each of the pair of nanosheet stacks including a plurality of nanosheets;
a pair of gate lines above the fin-type active region in the vertical direction, the pair of gate lines at least partially surrounding the plurality of nanosheets and extending lengthwise in a second horizontal direction that crosses the first horizontal direction;
a pair of gate dielectric films contacting a lower surface of the pair of gate lines and two sidewalls of the pair of gate lines;
a plurality of insulating spacers on the two sidewalls of the pair of gate lines;
a pair of capping insulating patterns on upper surfaces of the pair of gate lines;
a source/drain region on the fin-type active region, between the pair of gate lines, the source/drain region contacting the plurality of nanosheets of the pair of nanosheet stacks; and
an inter-gate dielectric between the pair of gate lines and on the source/drain region,
wherein the inter-gate dielectric includes the silicon oxide film,
wherein the plurality of insulating spacers and the pair of capping insulating patterns include the nitride film,
wherein the forming the hole comprises exposing, by the hole, the source/drain region through the inter-gate dielectric by performing the selective cycle etching, the performing the selective cycle etching comprising selectively etching only the inter-gate dielectric from among the inter-gate dielectric and the pair of capping insulating patterns, and
wherein the method further comprises, forming, after the forming the hole, a source/drain contact by filling an inside of the hole with a conductive material.

19. A method of manufacturing an integrated circuit device, the method comprising:
forming, on a substrate, a structure including a silicon oxide film and a nitride film; and
performing selective cycle etching that selectively etches only the silicon oxide film from among the silicon oxide film and the nitride film in a plasma atmosphere by using an etching gas including an unsaturated compound having a boiling point of 0° C. or less at atmospheric pressure and represented by CₓH_{y}F_{z}, where 2≤x≤5, 1≤y≤9, and 1≤z≤9,
wherein the selective cycle etching comprises:
a first sub-operation comprising forming a protection film on a surface of each of the silicon oxide film and the nitride film by exposing each of the silicon oxide film and the nitride film to a first plasma atmosphere obtained from the etching gas and an inert gas, wherein the protection film includes radicals obtained from the etching gas;
a second sub-operation comprising forming a volatile gas layer by exposing a first resulting product having undergone the first sub-operation to a second plasma atmosphere obtained from the inert gas while the etching gas is blocked from being supplied to the first resulting product, wherein the volatile gas layer includes volatile by-products obtained from an interface between the silicon oxide film and the protection film due to a reaction between the silicon oxide film and the protection film;
a third sub-operation comprising separating the volatile by-products and the protection film from the surface of the silicon oxide film by exposing a second resulting product having undergone the second sub-operation to a third plasma atmosphere obtained from at least two gases including the inert gas and an oxygen-containing reactive gas; and
etching the silicon oxide film to an etch depth by repeating, a plurality of times, one cycle that includes the first sub-operation, the second sub-operation after the first sub-operation, and the third sub-operation after the second sub-operation.

20. The method of claim 19, wherein the nitride film includes SiN, SiON, SiCON, SiBN, or SiCN,
wherein the etching gas includes C₃HF₅ or C₃H₂F₄,
wherein the inert gas includes Ar, He, or N₂,
wherein the oxygen-containing reactive gas includes O₂,
wherein the first sub-operation is performed under a condition that activated ions in the first plasma atmosphere irregularly move without particular directionality,
wherein the second sub-operation is performed under a condition that activated ions in the second plasma atmosphere have directionality in a direction perpendicular to an upper surface of the substrate, and
wherein the third sub-operation is performed under a condition that activated ions in the third plasma atmosphere have directionality in the direction perpendicular to the upper surface of the substrate.
